(19) United States
(12) Patent Application Publication
(10) Pub. No.: US 2003/0170964 A1
(43) Pub. Date: Sep. 11, 2003

(54) Oxidation of ion implanted semiconductors

(75) Inventors: David Y. Kao, Meridian, ID (US); Fernando Gonzalez, Boise, ID (US)

Correspondence Address: GREGORY M. TAYLOR, WORKMAN, NYDEGGER & SEELEY, 1000 EAGLE GATE TOWER, 60 EAST SOUTH TEMPLE, SALT LAKE CITY, UT, 84111, US

(73) Assignee: Micron Technology, Inc.

(21) Appl. No.: 10/385,132

(22) Filed: Mar. 10, 2003

Related U.S. Application Data
(62) Division of application No. 08/720,693, filed on Oct. 2, 1996.

(51) Int. Cl. H01L 21/76

(52) U.S. Cl. 438/433; 438/424; 438/435

(57) ABSTRACT

An improved LOCOS method for forming a patterned silicon dioxide field region on a substrate assembly by implanting silicon ions into a silicon substrate. The implanted silicon ions partially randomize the lattice structure of the monocrystalline silicon in the silicon substrate and increase the availability of silicon to ambient oxygen, thus increasing the rate of oxidation of the silicon substrate. The implantation of the silicon substrate with silicon ions makes oxidation faster and reduces the formation of bird's beak structures, as compared to an unimplanted silicon substrate. The method may also incorporate a nitride spacer formed at a periphery of an opening in the silicon nitride hard mask. The nitride spacer decreases straggle and the dimension of the resultant silicon dioxide field region, such that the dimensions thereof are below photolithography resolution limits. An improved shallow trench isolation region is also taught and reduces cross-talk and allows active regions to be formed closer together. The improved shallow trench isolation region is formed with a method that includes implanting silicon ions into an isolation trench followed by formation of a thermal oxide in the isolation trench that has greater lateral dimensions at the bottom of the isolation trench than at the top. A layer of silicon nitride is deposited to fill the remainder of the isolation trench and form the shallow trench isolation region.

This application is a divisional of U.S. patent application Ser. No. 08/720,693, filed on Oct. 2, 1996, which is incorporated herein by reference.

### BACKGROUND OF THE INVENTION

1. The Field of the Invention

The present invention relates to methods for forming a patterned oxide region. More particularly, the present invention relates to methods of locally oxidizing a layer of material used in semiconductor technology to grow a patterned oxide region in a rapid manner and with minimal encroachment by bird's beak structures. The method of the present invention is particularly useful in forming field oxide regions that isolate individual memory cells in a MOS memory integrated circuit. The present invention also relates to shallow trench isolation regions and methods of forming the shallow trench isolation regions suitable for use in semiconductor technology.

2. The Relevant Technology

Integrated circuits are currently manufactured by an elaborate process in which a great number of electronic devices are integrally formed on a semiconductor wafer. The conventional electronic devices formed on the semiconductor wafer in the process of fabricating an integrated circuit include capacitors, resistors, transistors, diodes, and the like. In advanced integrated circuit manufacturing processes, hundreds of thousands of these electronic devices are formed on a single semiconductor wafer.

One frequently conducted portion of the process of manufacturing an integrated circuit is the formation of an insulating layer or portion of an insulating layer on a silicon substrate of a semiconductor wafer. Insulating layers are frequently formed from oxides of silicon, in a process which typically results in the formation of silicon dioxide (SiO₂).

When forming a blanket layer of silicon dioxide, a silicon substrate is simply exposed to oxygen or oxygen-containing gases or liquids, usually at an elevated temperature, and the oxide grows from the resulting reaction. This simple process is complicated, however, when the layer of silicon dioxide is intended to be patterned.

The conventional method for forming a patterned oxide region with thermal oxidation is referred to as the Local Oxidation of Silicon (LOCOS) and involves masking a silicon substrate and exposing the unmasked portions of the silicon substrate to dry oxygen or water vapor at a temperature of around 900° C. to 1150° C.

One type of patterned oxide region that is frequently constructed in forming an integrated circuit is a silicon dioxide field region, also known as a field oxide region (FOX). The silicon dioxide field region is used to electrically isolate transistors and capacitors from other transistors and capacitors, and in one application is used to electrically isolate individual memory cells in a MOS memory integrated circuit. The formation of a conventional silicon dioxide field region will be discussed in conjunction with FIGS. 1 through 3.

Under conventional LOCOS processes, the silicon dioxide field region is formed on a substrate assembly with the use of a silicon nitride hard mask. Substrate assembly is intended herein to mean a substrate having thereon one or more layers or structures. The arrangement by which the silicon nitride hard mask is prepared is shown in FIG. 1, where a silicon substrate 12 is shown situated on a semiconductor wafer 10. Formed on silicon substrate 12 is a pad oxide layer 14. After forming pad oxide layer 14, a silicon nitride layer 16, typically Si₃N₄, is deposited thereon. Typically, silicon nitride layer 16 is deposited with chemical vapor deposition (CVD) using ammonium and silane or other silicon source gases. Subsequently, a photoresist mask 18 is formed and patterned with photolithography.

As shown in FIG. 2, photoresist mask 18 is used in etching silicon nitride layer 16 to form a patterned silicon nitride hard mask 20. Thereafter, as seen in FIG. 3, photoresist mask 18 is stripped off.

FIG. 3 shows the results of a subsequent step of conventional LOCOS processes, wherein exposure of silicon substrate 12 to oxygen at an elevated temperature results in an oxidation reaction that causes the growth of silicon dioxide field regions 22 in unmasked openings where silicon substrate 12 is not covered by silicon nitride hard mask 20.

Silicon dioxide field regions 22 created by conventional LOCOS processes are typically thicker at the center and taper toward the edges, with a substantially oblong cross-section. The silicon dioxide field regions also form sharp corners at the outer periphery known as “bird's beak” structures 24. Bird's beak structures 24 tend to grow laterally during the oxidation reaction, causing bird's beak structures 24 to grow oxide underneath silicon nitride hard mask 20 and to encroach into adjoining active regions 12a where transistors and other semiconductor devices are intended to be formed.

The nonuniform profile of silicon dioxide field regions 22 causes a reduction in isolation capability. The reduced isolation capability is a limitation to the compactness with which silicon dioxide field regions 22 can be formed.

Forming silicon dioxide field regions 22 created by conventional LOCOS processes to have a more compact profile would reduce the isolation capability of silicon dioxide field regions 22 to a point that would cause electrical current leakage between source and drain regions of transistors in adjoining active regions 12a on either side of silicon dioxide field regions 22. The leakage of electrical current is initiated by current carrying structures produced at a later point in the fabrication process.

The current carrying structures, such as word line gate regions, are frequently located on top of silicon dioxide field regions and cause a voltage under the silicon dioxide field regions that results in cell to cell leakage of electrical current between parasitic field transistors in adjoining active regions 12a when the isolation capability of silicon dioxide field regions 22 is not sufficient. The cell to cell leakage of electrical current is called “cross-talk.” Cross-talk is undesirable in that it interferes with signals being sent to the parasitic field transistors in adjoining active regions 12a, ultimately causing a failure of the integrated circuit to perform its intended function. While it is known that producing silicon dioxide field regions 22 to be thicker and to have a more rectangular profile would prevent current from conducting between parasitic field transistors at low voltages and would help to eliminate cross-talk, conventional LOCOS processes do not provide sufficient control over the profile of silicon dioxide field regions 22 to do so.

The encroachment of bird's beak structures 24 into active regions 12a is also a barrier to integrated circuit miniaturization efforts. The thinness of bird's beak structures 24 at their outer periphery reduces their isolation capability, and the elongated and pointed geometry prohibits silicon dioxide field regions 22 from being densely packed. The density of an arrangement of silicon dioxide field regions 22 is measured as “isolation pitch.” Isolation pitch is limited by the oxide encroachment under silicon nitride hard mask 20, which in turn results in the usable space of active regions 12a being reduced after field oxidation is complete. As advancements in integrated circuits cause geometries to shrink, bird's beak structures 24 are becoming a dominant limiting factor to minimizing the isolation pitch and therefore to maximizing the number of semiconductor devices such as memory cells that can be effectively packed into semiconductor wafer 10.

A further type of patterned oxide region that is increasingly being used in forming integrated circuits is the shallow trench isolation region. A conventional method of forming a shallow trench isolation region is illustrate in FIGS. 1 and 4 through 6. Under this method, as shown in FIG. 1, silicon substrate 12 is provided and typically covered with a thin oxide layer 14. A silicon nitride layer 16 is then deposited over thin oxide layer 14, and a photoresist mask 18 is formed on silicon nitride layer 16. When forming a shallow trench isolation region, the openings between islands in photoresist mask 18 are spaced closer together.

Silicon nitride layer 16 is etched with the use of photoresist mask 18 to form a silicon nitride hard mask 20 such as is shown in FIG. 4. Once masked with silicon nitride hard mask 20, one or more isolation trenches 26 are etched into silicon substrate 12 using silicon nitride hard mask 20 to block active regions 12a located between isolation trenches 26 from being etched. As shown in FIG. 5, once isolation trenches 26 are formed, a thermal oxide layer 28 is grown on the sidewalls of isolation trenches 26 by exposing isolation trenches 26 to oxygen at an elevated temperature which causes an oxidation reaction, as discussed above.

After growing thermal oxide layer 28, and as shown in FIG. 5, a further step comprises the deposition of an inner oxide layer 30. Inner oxide layer 30 is typically deposited using one of a number of existing forms of TEOS deposition. Silicon nitride hard mask 20 is thereafter removed, typically using CMP with thin oxide layer 14 serving as an etch stop barrier. In so doing, a portion of inner oxide layer 30 is also etched, and the resulting structure is as appears in FIG. 6, wherein can be seen completed shallow trench isolation regions 32.

The shallow trench isolation region formation process has significant advantages over the LOCOS process in that shallow trench isolation regions 32 formed thereby are narrower, yet have adequate isolation capability allowing active regions 12a to be spaced closer together. This provides for greater density of semiconductor devices and thus greater miniaturization of the integrated circuit being formed. Shallow trench isolation regions 32 are also not complicated by the imposing bird's beak structures 24 of the LOCOS process.

Nevertheless, the formation of shallow trench isolation regions 32 has its drawbacks. The process is time consuming due to the greater number of steps and also due to the depth to which isolation trenches 26 must be etched. Additionally, if shallow trench isolation regions 32 are not formed sufficiently wide and deep, cross-talk can also occur between parasitic field transistors in adjoining active regions 12a, as discussed above in reference to the LOCOS process. Consequently, shallow trench isolation regions 32 can still consume a great amount of space on silicon substrate 12, which could otherwise be used for forming semiconductor devices.

It is apparent from the above discussion that a need exists in the art for a method for forming a silicon dioxide field region that has a more desirable profile and that reduces encroachment by bird's beak structures. Such a method would be especially beneficial if silicon dioxide field regions with reduced isolation pitch and high isolation capabilities could be formed thereby.

It is also apparent that a need exists for an improved method of forming shallow trench isolation regions in a more compact manner and with less depth. Such a method is needed that also provides increased isolation capability and resistance to cross-talk.

### SUMMARY OF THE INVENTION

A method is provided for forming a patterned oxide region on a substrate assembly, preferably situated on a semiconductor wafer, using implantation of a selected type of ions to speed up patterned oxide region growth, improve patterned oxide region profile, and reduce encroachment by bird's beak structures. The term substrate assembly is intended herein to mean a substrate having one or more layers or structures formed thereon. As such, the substrate assembly may be, by way of example and not by way of limitation, a doped silicon semiconductor substrate typical of a semiconductor wafer.

In general, the inventive method forms an oxide region on a substrate assembly by first bombarding a selected region of a layer substantially composed of a first material with ions thereof. The layer substantially composed of the first material is situated on a substrate assembly. The substrate assembly will preferably be situated on a semiconductor wafer. After ion bombardment, the implanted layer is oxidized by exposure to oxygen.

One embodiment of the method of the present invention results in the formation of a patterned oxide region in the form of a silicon dioxide field region. In this embodiment, a semiconductor wafer is first provided. A layer of material in which one or more patterned oxide regions are to be formed is formed on the semiconductor wafer. The silicon substrate is cleaned and then masked with a patterned masking substrate such as a silicon nitride hard mask. In so doing, the silicon nitride hard mask can be etched with either a stop-on-oxide etch process that uses a pad oxide layer as an etch barrier or a selective stop-on-silicon etch process. Selected areas in which the silicon oxide regions are to be grown are left exposed as unmasked openings.

Once the silicon substrate is provided and the silicon nitride hard mask has been formed thereon, ions are implanted into the unmasked openings in the silicon nitride hard mask. The implanted ions are of a selected type that does not significantly alter the electrical charge characteristics of the layer of material and that increases the rate with which the layer of material oxidizes. The increased rate of oxidation in one embodiment is due to the ions of the selected type providing an increased availability of a source material for the oxidation reaction that forms an oxide of the material from which the layer of material is composed. Accordingly, in a preferred embodiment wherein the layer of material comprises silicon, the implanted ions also comprise silicon. Other types of ions may also be implanted together with the selected type of ions.

The implantation of ions causes the lattice structure of the monocrystalline silicon material in the silicon substrate to partially randomize. This increases the rate with which the oxidation reaction progresses and also increases the thickness of the resulting silicon dioxide field region. The implanted silicon ions provide interstitials in the silicon substrate crystalline lattice that are homogenous to the silicon substrate and that provide a greater source for the oxidation reaction. This increases the ratio of available silicon and speeds up the oxidation reaction. Of course, one skilled in the art will recognize that when oxidizing layers of material other than silicon, suitable ions that provide a source for the corresponding reaction should be selected.

The oxidation reaction is preferably conducted by exposing the semiconductor wafer to dry oxygen or water at an elevated temperature. More rapid oxidation of the silicon is possible than in conventional LOCOS processes described above due to the implantation of silicon ions into a monocrystalline silicon substrate on a semiconductor wafer. Less oxidation time allows less time for lateral growth of the silicon dioxide region so as to prevent significant formation of bird's beak structures. The resulting silicon dioxide field region, also known as a field oxide (FOX) region, has a more rectangular cross-sectional profile. It also has less pronounced, more longitudinally oriented corners at the outer periphery so that bird's beak structure formation is reduced and so that less encroachment of bird's beak structures into the adjacent active regions occurs. The profile of the silicon dioxide field region also provides greater electrical isolation between adjacent active regions and allows the adjacent active regions to be formed more compactly, thereby facilitating greater miniaturization of the integrated circuit.

In an alternative embodiment, a nitride spacer is formed at the periphery of an unmasked opening in the silicon nitride hard mask. The nitride spacer reduces the dimensions of the unmasked opening prior to ion implantation. This causes the resulting silicon dioxide field region formed against the nitride spacer to be smaller. A smaller silicon dioxide field region also allows the adjacent active regions to be spaced closer together for even greater miniaturization. The nitride spacer also helps to seal off the pad oxide layer, particularly when a stop-on-silicon nitride layer etch process is used, and further reduces the formation of bird's beak structures in the resulting silicon dioxide field regions. The nitride spacer is formed by any suitable process. Chemical vapor deposition and photolithography patterning and etching is currently preferred. Using the nitride spacer, silicon dioxide field regions having dimensions below photolithography resolution limits can be formed.

The present invention forms a silicon dioxide field region in less time than conventional LOCOS processes. The present invention forms the silicon dioxide field region with a thicker, more desirable profile that provides better isolation. The profile of the silicon dioxide field region formed by the inventive method encroaches less into the active regions adjacent to the silicon dioxide field region than prior art methods, thus allowing the adjacent active regions to be formed more compactly. The resultant patterned oxide regions can thus be formed smaller for greater miniaturization of the integrated circuit. With the use of the provided nitride spacers, the silicon dioxide field region can be formed with dimensions that are below photolithography resolution limits.

The present invention also provides a shallow trench isolation region and method for forming the shallow trench isolation region. The shallow trench isolation region is suitable for use in electrically isolating adjacent active regions on a semiconductor wafer. In an initial step of forming the shallow trench isolation region, an isolation trench is formed in a layer of material, preferably a silicon substrate, on a semiconductor wafer. The isolation trench is selectively etched using a masking substrate that is impermeable to implanted ions, and that preferably comprises a silicon nitride hard mask.

Thereafter, ions are implanted into the shallow trench isolation region through openings in the silicon nitride hard mask. The ions are preferably of a selected type that causes the layer of material to oxidize at a more rapid rate. In one embodiment, the ions of the selected type contribute a source for increasing the reaction which forms an oxide of the layer of material. Consequently, when the shallow trench isolation region is formed in a layer of material comprising silicon, the ions of the selected type are preferred to be of silicon. Of course, other ions could also be concurrently implanted. The ions may be implanted with an angle orthogonal to the surface of the semiconductor wafer, or the ions may be implanted at an angle other than orthogonal to the surface of the silicon conductor wafer. Preferably, the angle of the implanted ions is within 0 and 10° from a direction orthogonal to the surface of the semiconductor wafer.

Once the ions are implanted, the semiconductor wafer is exposed to oxygen at an elevated temperature to grow a thermal oxide layer in the isolation trench. The thermal oxide layer grows on the sidewalls of the isolation trench and also at the bottom of the isolation trench where the implanted ions have impacted. The implanted ions diffuse as interstitials of the crystal lattice at the bottom of the isolation trench in an outward expansion that results in a growth of the thermal oxide layer in a direction which protrudes outward laterally at the bottom of the isolation trench. Implanting the ions with an angle of greater than 0° from the orthogonal direction causes the thermal oxide layer to protrude outward at the bottom even more than does an implant that is conducted with a direction orthogonal to the surface of the semiconductor wafer.

In a further step, an inner oxide layer is deposited in the isolation trench with TEOS in a conventional manner, after which the silicon nitride hard mask is removed with a stop on oxide planarization process that also somewhat reduces the height of the protruding portion of the inner oxide layer. A shallow trench isolation region results that is similar to the shallow isolation trench of the prior art with the exception that the bottom of the shallow trench isolation region is extended outward laterally and also somewhat vertically. Consequently, the shallow trench isolation regions can be formed more compactly yet with greater resistance to cross-talk than shallow trench isolation regions of the prior art.

### BRIEF DESCRIPTION OF THE DRAWINGS

In order that the manner in which the above-recited and other advantages of the invention are obtained will be understood, a more particular description of the invention briefly described above will be rendered by reference to specific embodiments thereof which are illustrated in the appended drawings. Understanding that these drawings depict only typical embodiments of the invention and are not therefore to be considered limiting of its scope, the invention will be described and explained with additional specificity and detail through the use of the accompanying drawings briefly outlined below.

FIG. 1 is a cross-sectional view of a portion of a substrate assembly on a semiconductor wafer showing several initial steps in a conventional method of forming a silicon dioxide spacer region, including the formation of a pad oxide layer, a nitride layer, and a patterned photoresist mask.

FIG. 2 is a cross-sectional view of the portion of the substrate assembly of FIG. 1 showing a further step of patterning a silicon nitride hard mask.

FIG. 3 is a cross-sectional view of the portion of the substrate assembly of FIG. 2, showing the results of a further step of growing a patterned silicon dioxide field region. FIG. 3 also illustrates the resulting encroaching bird's beak structures.

FIG. 4 is a cross-sectional view of a portion of the semiconductor wafer of FIG. 1, showing steps used in a conventional method for forming a shallow trench isolation region, the steps including forming a silicon nitride hard mask and etching an isolation trench.

FIG. 5 is a cross-sectional view of a portion of the semiconductor wafer of FIG. 4, showing further steps of growing a thermal oxide layer in the isolation trench and depositing an inner oxide layer in the isolation trench.

FIG. 6 is a cross-sectional view of a portion of the semiconductor wafer of FIG. 5 showing the results of a further step of removing a silicon nitride hard mask and also showing the resulting shallow trench isolation regions.

FIG. 7 is a cross-sectional view of the portion of the substrate assembly of FIG. 2, showing a step in a method of the present invention for forming patterned oxide regions, wherein silicon atoms are implanted into exposed regions of a silicon substrate at regions that are left exposed by the silicon nitride hard mask.

FIG. 8 is a cross-sectional view of the portion of the substrate assembly of FIG. 7, showing the results of a further step of growing silicon dioxide regions, which in comparison with FIG. 3 produces a thicker and more dense silicon dioxide region with reduced encroachment by bird's beak structures.

FIG. 9 is a cross-sectional view of the portion of the substrate assembly of FIG. 2, showing steps of an alternate embodiment of the method for forming patterned oxide regions, wherein a nitride spacer is formed at the periphery of an opening in the silicone nitride hard mask and silicon atoms are implanted into the opening.

FIG. 10 is a cross-sectional view of the portion of the substrate assembly of FIG. 9, showing the results of a further step of growing silicon dioxide regions, which in comparison with FIG. 3 produces a thicker and more dense silicon dioxide region with reduced encroachment by bird's beak structures.

FIG. 11 is a cross-sectional view of the portion of the substrate assembly of FIG. 1, showing several initial steps in a method of the present invention for forming a shallow trench isolation region, the steps including forming a silicon nitride hard mask, etching an isolation trench, and implanting ions into the isolation trench.

FIG. 12 is a cross-sectional view of the portion of the substrate assembly of FIG. 11, showing the results of a further step of growing a thermal oxide layer on the sides and bottom of the isolation trench.

FIG. 13 is a cross-sectional view of the portion of the substrate assembly of FIG. 12, showing further steps of depositing an oxide layer in the remainder of the isolation trench and removing the silicon nitride hard mask, and also showing the resulting shallow trench isolation regions.

FIG. 14 is a cross-sectional view of the portion of the substrate assembly of FIG. 1, showing steps of an alternate embodiment of the method for forming a shallow trench isolation region, wherein a silicon nitride hard mask is formed, an isolation trench is etched in the silicon substrate, and ions are implanted into the isolation trench at an angle other than orthogonal to the plane of the semiconductor wafer.

FIG. 15 is a cross-sectional view of the portion of the substrate assembly of FIG. 14 showing the shallow trench isolation regions formed by the alternate embodiment wherein ions are implanted into the isolation trench at an angle other than orthogonal to the plane of the semiconductor wafer.

### DETAILED DESCRIPTION OF THE INVENTION

One method of the present invention will be initially discussed by reference to an embodiment comprising a modification of the conventional LOCOS process discussed above, and is used to form a patterned oxide region. The method of forming a patterned oxide region using LOCOS will be explained in conjunction with FIGS. 1, 2, 7, and 8, in an embodiment wherein the patterned oxide region comprises a silicon dioxide field region.

FIG. 1 shows the initial steps of the method of the present invention wherein a volume of semiconductor material in a substrate assembly is being oxidized. As defined herein, a substrate assembly is a substrate on which may be formed one or more layers. In the depicted embodiment, the substrate assembly comprises a silicon substrate 12, which is provided on a semiconductor wafer 10, and the volume of semiconductor material comprises the monocrystalline silicon of silicon substrate 12. Of course the present invention could be employed for other types of semiconductor materials and on substrate assemblies other than a semiconductor wafer.

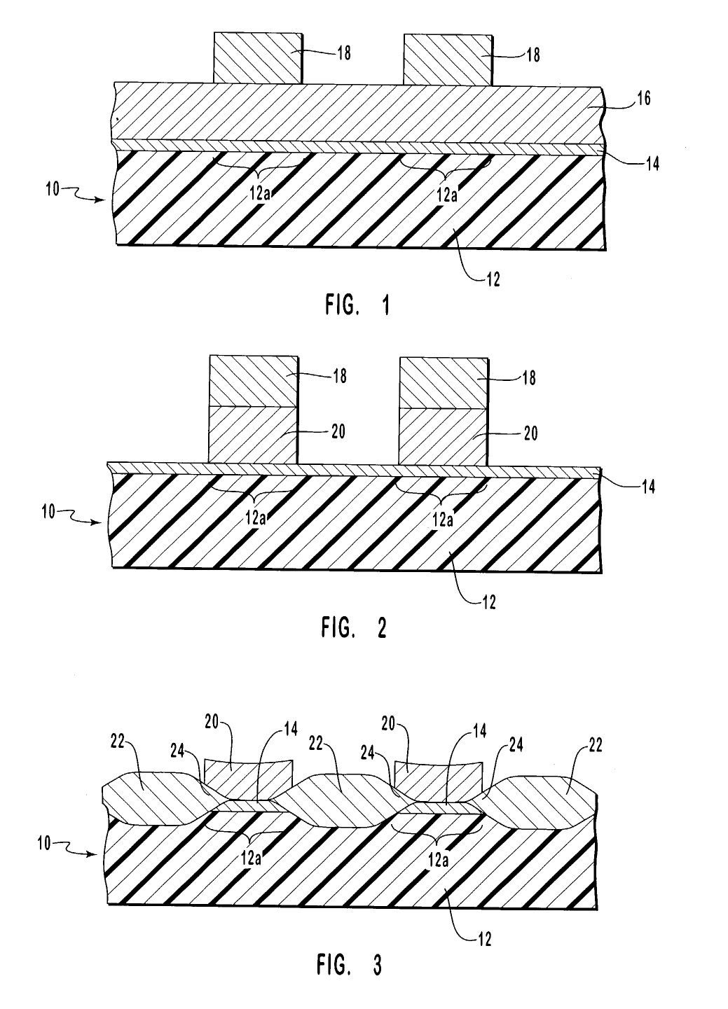

The method of the present invention shares the steps of conventional LOCOS processes up until the stage of FIG. 2. Thus, a thin pad oxide layer 14 is formed on silicon substrate 12. Pad oxide layer 14 is preferably formed with a thickness of about 100 to about 200 angstroms. As shown in FIG. 2, a masking substrate such as a silicon nitride hard mask 20 is formed over silicon substrate 12, and is preferably etched and patterned in a conventional manner using a photoresist mask 18 that is patterned with photolithography.

When etching silicon nitride hard mask 20 a stop-on-oxide etch process can be used that employs pad oxide layer 14 as an etch barrier. A selective stop-on-silicon etch process can also be used that etches to the bottom of pad oxide layer 14 and stops on silicon substrate 12. Silicon nitride hard mask 20 is patterned in a manner that forms unmasked openings 20a over selected areas of silicon substrate 12 located where the silicon dioxide field regions are intended to be formed.

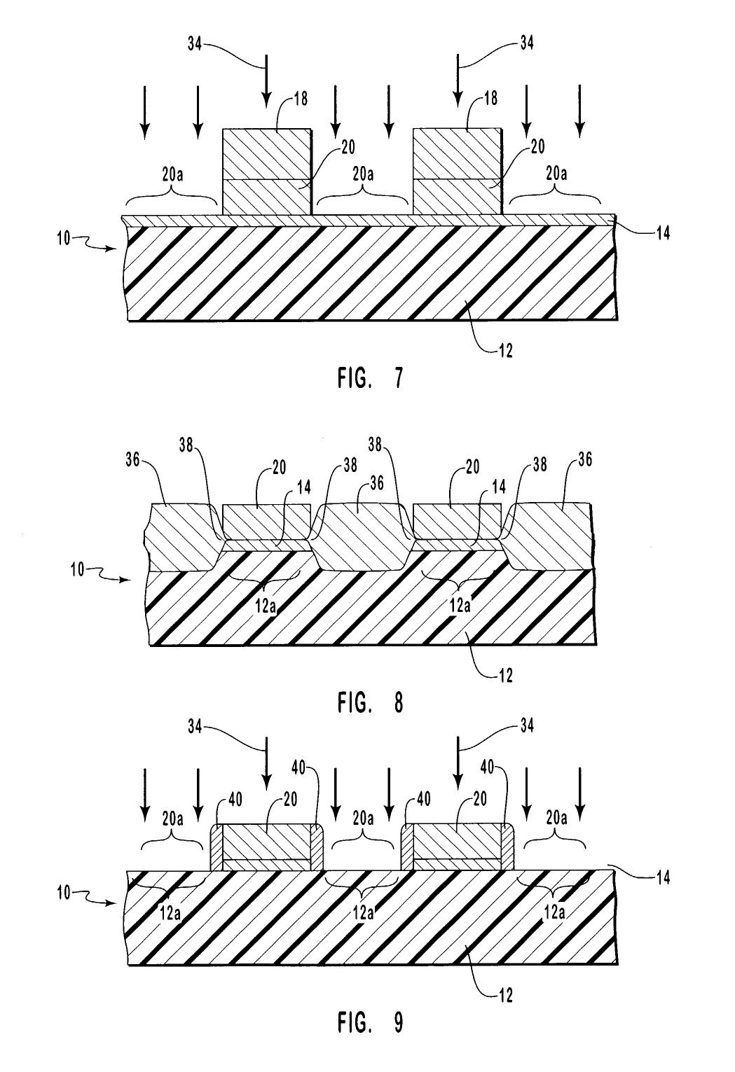

FIG. 7 illustrates a further step in the present invention that is conducted after the conventional steps of FIG. 2. As shown in FIG. 7, ions represented by arrows 34 are implanted into unmasked openings 20a in silicon nitride hard mask 20. Photoresist mask 18 is preferably allowed to remain over patterned silicon nitride hard mask 20 during the implantation in order to better control the area of impact of the implanted ions.

The implanted ions are of a selected type that increases the rate at which a layer of material oxidizes. In the depicted embodiment, the layer of material comprises silicon substrate 12. In one embodiment, the increased rate of oxidation occurs because the ions of the selected type provide increased availability of a source material for the oxidation reaction that forms an oxide of the material from which the layer of material is composed. The implanted ions also preferably do not alter the electrical conductivity type of the layer of material. This is advantageous in that it provides more flexibility to the process by not altering the conductivity of active regions 12a that are typically being electrically isolated by the silicon dioxide field region. It also provides for greater isolation capability of the resultant oxide.

Without sufficient isolation capability, the parasitic field transistor threshold voltage that causes cross-talk leakage between active regions 12a is quite low, thereby increasing the occurrence of cross-talk leakage between adjacent parasitic field transistors such as MOS memory cells. The voltage required to cause the individual transistors being created to enter an operational state can also be altered as a result of insufficient isolation capability.

In one embodiment, the ions of the selected type are implanted with a zero degree angle, as measured from a direction orthogonal to the plane of semiconductor wafer 10. The zero degree angle minimizes “straggle,” which is the diffusion of atoms within the silicon substrate lattice that results from the implantation of ions. Atoms diffused by the straggle phenomenon can migrate to the edges of the selected implantation area and result in an increase in bird's beak structure formation.

The ions of a selected type are preferably implanted to a depth in the range from about 200 angstroms to about 2,000 angstroms. Suitable results can be achieved using a high current medium energy implanter such as the Varian E1000 produced by Varian Associates of Palo Alto, Calif. The Varian E1000 implanter is preferably set at about 50 KeV to 200 KeV and at a current in a range of from about 2 mA to about 10 mA. The implantation dose of ions that are implanted into silicon substrate 12 is preferably in the range of from about 1×10¹⁵ atoms per cm² to about 6×10¹⁶ atoms per cm². A more preferred implantation dose is about 1×10¹⁶ atoms per cm².

Silicon nitride hard mask 20 or any other material that is used as a masking substrate is selected to be generally impermeable to implanted ions. This causes the ions to be implanted only into the selected areas of silicon substrate 12 located under unmasked openings 20a in silicon nitride hard mask 20.

The silicon ions are implanted as interstitials outside of the crystal lattice structure of the silicon substrate of the semiconductor wafer. The implantation of ions causes the lattice structure of the monocrystalline silicon material in the silicon substrate to partially randomize. The paths created during the partial randomization allow oxygen to more readily enter into the crystal lattice structure to form silicon dioxide with the silicon that is implanted and the silicon that was already present in the crystal lattice structure of the silicon substrate. The ready availability of silicon to bond with oxygen causes the oxidation reaction to occur quicker and with the expenditure of less energy than would occur for monocrystalline silicon. As such, the thickness of the resultant silicon dioxide region is also increased.

Thus, the selected areas that are implanted sustain a more rapid oxidation reaction than unimplanted areas. This quick reaction effectively speeds up oxide growth in a vertical direction and slows down oxide growth in a horizontal direction, which consequently reduces the size of bird's beak structures in the resulting silicon dioxide field regions.

In a preferred embodiment, silicon substrate 12 comprises monocrystalline silicon and the implanted ions also comprise silicon. The implantation of silicon ions as interstitials provides an increased availability of silicon to the oxidation reaction which reacts silicon and oxygen to form silicon dioxide, as discussed above, thereby speeding up the oxidation reaction to an even greater degree and further increasing the thickness with which the resulting silicon dioxide field regions can be formed.

FIG. 8 depicts a further step in the method of the present invention, wherein semiconductor wafer 10 is placed in an oxidation furnace and exposed to water or oxygen at an elevated temperature to initiate the oxidation reaction and form silicon dioxide field regions 36. The oxidation reaction can be conducted at a high pressure which allows the temperature and time required for the oxidation reaction to be lowered. The oxidation reaction can be conducted at pressures of up to 25 atmospheres. A preferred pressure range is about 1 to 25 atmosphere, and a more preferred range is about 5 to 25 atmospheres. Most preferably, the oxidation reaction is conducted with a pressure in the range of about 5 to 10 atmospheres. The higher pressure provides better control over process parameters and saves on thermal budget while still allowing the growth of a thick oxide with high isolation capability.

The implantation of ions typically results in damage to silicon substrate 12. A follow up thermal treatment step is conducted to heal the damage and to prevent the propagation of defect regions. Optimizing the implant parameters of dose, dose energy, and depth also helps to keep damage in silicon substrate 12 to a minimum. The follow-up thermal treatment step also functions to reduce surface charges in silicon dioxide field regions 36 by causing unreacted silicon to migrate out of silicon dioxide field regions 36. The surface charges are undesirable in that they reduce the isolation capability of silicon dioxide field regions 36.

The method of the present invention provides a desirable level of control over the profile of silicon dioxide field regions 36, and results in silicon dioxide field regions 36 that have a thick, semi-rectangular cross-sectional profile. A dense allocation of oxide is provided by the method of the present invention, such that silicon dioxide field regions 36 can be of a compact size and also maintain a sufficient isolation capability. Silicon dioxide field regions 36 also have less pronounced, more longitudinally oriented corners at the periphery than silicon dioxide field regions formed by conventional LOCOS processes so that bird's beak structures 38 are reduced and encroach less into active regions 12a than the silicon dioxide field regions of the conventional LOCOS processes.

The method of the present invention is also quicker than the conventional LOCOS processes, saving time and energy. The method of the present invention can be implemented without specialized equipment and without significantly slowing down process flow.

The rapid speed of formation of silicon dioxide field regions 36 of the present invention provides flexibility in the selection of the thickness of pad oxide layer 14. The rapid speed of formation also allows pad oxide layer 14 to be relatively thin, because there is less time for resultant stress to occur due to a more rapid oxidation period than the conventional LOCOS method. Pad oxide layer 14 preferably has a thickness of between about 100 to 200 angstroms.

The resultant silicon dioxide field regions 36 are more uniform than silicon dioxide field regions produced by the conventional LOCOS processes, have greater depth, and have smaller and less pronounced bird's beak structures 38 than the silicon dioxide field regions of the conventional LOCOS processes. This allows for more compact active regions 12a with a lower isolation pitch, facilitating greater miniaturization of the integrated circuit than can be achieved with conventional LOCOS processes.

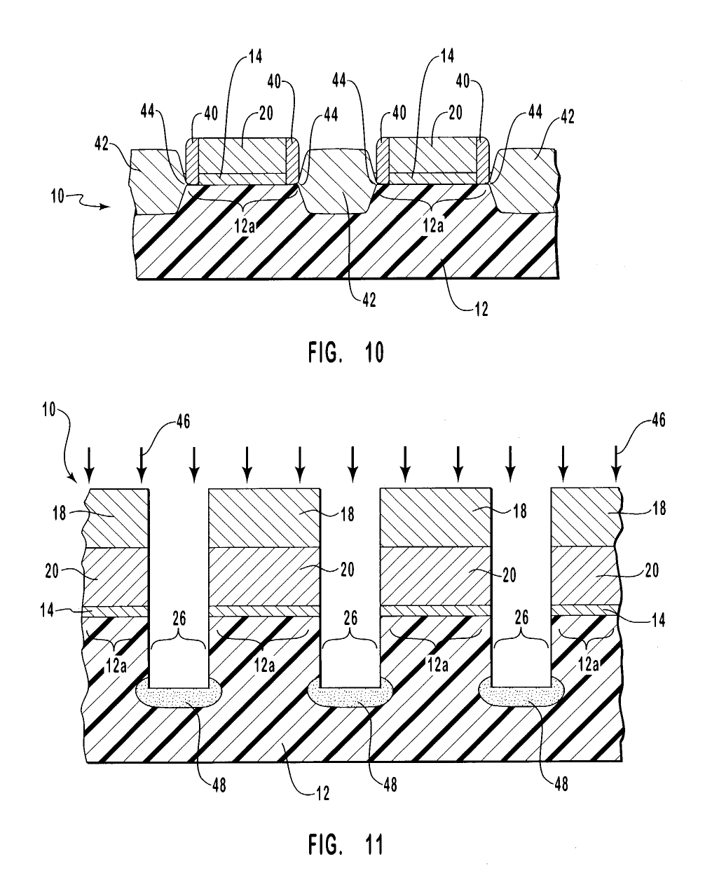

While the method of the present invention has been illustrated in relation to one specific embodiment, the invention is not intended to be restricted to this embodiment and may be conducted in other manners as well. For instance, a further embodiment is discussed in FIGS. 9 and 10, wherein the dimensions of the selected areas that are implanted are selectively controlled. Under this embodiment, as shown in FIG. 9, one or more nitride spacers 40 are formed, subsequent to the steps of FIG. 2, at opposing edges of silicon nitride hard mask 20. Nitride spacers 40 are preferably formed from a silicon nitride layer, which is formed in a conventional manner.

Nitride spacers 40 are small, preferably comprising about 0.05 to 0.15 microns in width, but significantly reduce isolation pitch, preferably leaving an unmasked opening 20a of between about 0.05 to 0.1 microns wide and preferably about 0.05 microns wide, which is finer than can currently be achieved with conventional photolithography.

Silicon nitride hard mask 20 is preferably etched in this embodiment with the stop-on-silicon etching process, and photoresist mask 18 is preferably removed before ion implantation. After removing photoresist mask 18, ions are implanted into open areas 20a in silicon substrate 12. Ion implantation is represented in FIG. 9 by arrows 34.

As shown in FIG. 10, semiconductor wafer 10 is subsequently exposed to oxygen to form silicon dioxide field regions 42. Silicon nitride hard mask 20 and nitride spacers 40 can then be removed.

Nitride spacers 40 seal themselves to silicon substrate 12, sealing off pad oxide layer 14, thereby providing less opportunity for lateral oxide growth beneath silicon nitride hard mask 20. Consequently, silicon dioxide field regions 42 of FIG. 7 are formed to have even more reduced bird's beak structures 44 than silicon dioxide field regions 36 of the previous embodiment. Additionally, substantially no bird's beak structure 22 of the prior art will form underneath silicon nitride hard mask 20 or nitride spacers 40. The resulting silicon dioxide field regions 42 are more compact than can be formed with conventional processes yet, due to a more rectangular cross section and reduced bird's beak structures 44, are still capable of maintaining sufficient isolation capability to provide proper electrical isolation and prevent cross-talk. The compactness and finer spacing reduces isolation pitch, thereby assisting in the miniaturization process.

While the anisotropic dry etch step used in forming nitride spacers 40 requires additional time and expense, in many applications the advantages of the nitride spacer embodiment described above will outweigh this detriment. One particular advantage is that silicon dioxide field regions 42 can be formed more compactly than is possible without nitride spacers 40 due to limitations of current photolithography resolution.

The present invention also provides a shallow trench isolation region and a method of forming the shallow trench isolation region. The method will be described herein by reference to FIGS. 1, 4, and 11 through 15. The shallow trench isolation region is useful for electrically isolating adjacent active regions on a semiconductor wafer. Initially, under the method of the present invention, one or more isolation trenches 26 are patterned and formed. Thus, as shown in FIG. 1, a photoresist mask 18 is formed over a layer of material that is impermeable to implanted ions, such as silicon nitride layer 16 of the depicted embodiment. Silicon nitride layer 16 is formed over a thin oxide layer 14 on a silicon substrate 12 of a semiconductor wafer 10.

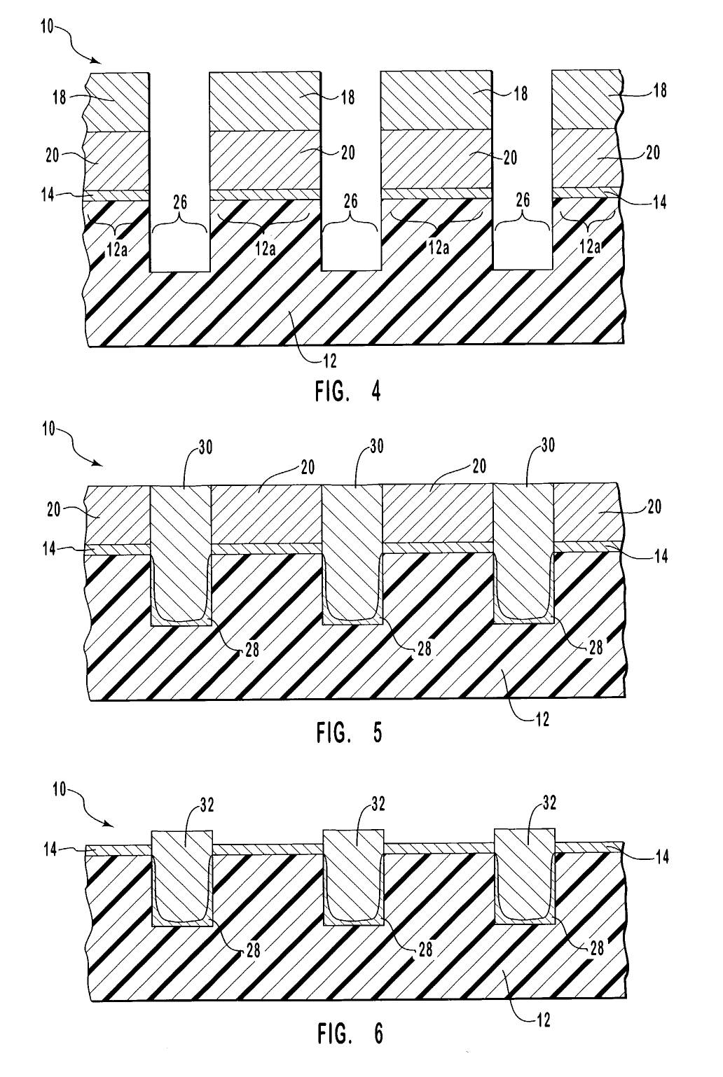

As shown in FIG. 4, silicon nitride hard mask 20 is etched using photoresist mask 18 to form isolation trenches 26. In so doing, a triple-recipe etch process is preferably used. The triple-recipe etch process is conducted in a single chamber using three sequential recipes which first etch nitride to form silicon nitride hard mask 20, then etch oxide to etch through thin oxide layer 14, and finally that etch silicon to form isolation trenches 26 in silicon substrate 12.

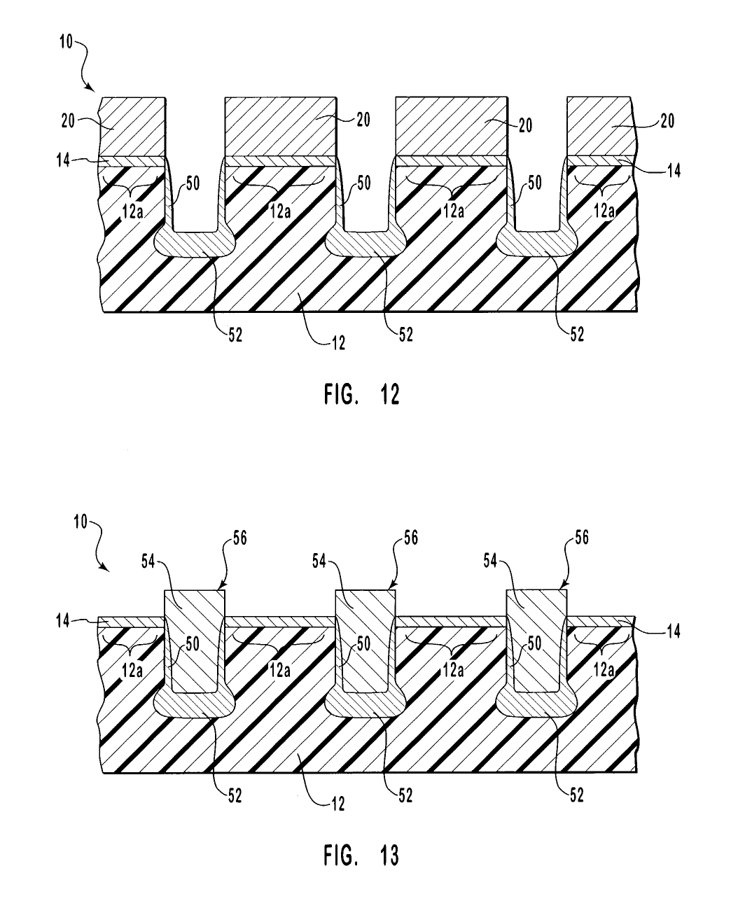

As shown in FIG. 11, a further step, conducted after formation of isolation trenches 26, comprises implanting ions into isolation trenches 26. The ion implantation step is conducted with the use of silicon nitride hard mask 20. It is also preferred that photoresist mask 18 be left in place after isolation trenches 26 have been etched in order to assist in maintaining the directionality of the implanted ions. Ion implantation is represented by arrows 46. Due to the impermeability of the implanted ions into silicon nitride hard mask 20, the implanted ions only impact the sidewalls and bottom of isolation trenches 26. It is preferred that the implanted ions be implanted with an angle that is either orthogonal to the surface of semiconductor wafer 10 or within 10° from being orthogonal to the surface of semiconductor wafer 10. The substantially orthogonal angle will allow relatively few ions to be implanted into the sidewalls of isolation trenches 26, and will cause more ions to be implanted into the bottom of isolation trenches 26, as shown in FIG. 11, wherein the location of implanted ions are depicted as implanted regions 48.

The implanted ions cause straggle that pushes interstitial silicon atoms outward in the bottom of isolation trenches 26. This outward diffusion of atoms causes implanted regions 48 to extend out laterally and vertically from the dimensions of isolation trenches 26. The outward diffusion of atoms also occurs without the need for any form of thermal treatment.

The implanted ions are of a selected type that increase the rate at which a layer of material oxidizes. In the depicted embodiment, the layer of material comprises silicon substrate 12. In one embodiment, the increased rate of oxidation occurs because the ions of the selected type provide an increased availability of a source material for the oxidation reaction that forms an oxide of the material from which the layer of material is composed. The implanted ions also preferably do not alter the electrical conductivity type of the layer of material. This is advantageous in that it provides more flexibility to the process by not altering the conductivity of active regions 12a that are typically being electrically isolated by the shallow trench isolation regions. It also provides for greater isolation capability of the resultant oxide.

A further step is illustrated in FIG. 12, wherein semiconductor wafer 10 is exposed to oxygen at an elevated temperature. The exposure to oxygen causes the growth of sidewall thermal oxide layers 50 on the sidewalls of isolation trenches 26. Sidewall thermal oxide layers 50 preferably have a thickness of about 50 to about 200 angstroms. The exposure to oxygen also causes the growth of laterally protruding, bulbous bottom thermal oxide regions 52 in the bottom of isolation trenches 26. Due to the shape of implanted regions 48 resulting from the implantation and diffusion of ions, bottom thermal oxide regions 52 form protruding edges that extend outward laterally to a greater degree than does sidewall thermal oxide layer 50. Bottom thermal oxide layers 52 also extend downward vertically with a thickness that is greater than the horizontal thickness of sidewall thermal oxide layers 50. As with the shallow trench isolation region method discussed above, the growth of sidewall thermal oxide regions 50 and bottom thermal oxide regions 52 can be conducted at the above-discussed higher pressure ranges to lower the required temperatures and to provide better control over process parameters while still growing a thick oxide with high isolation capabilities.

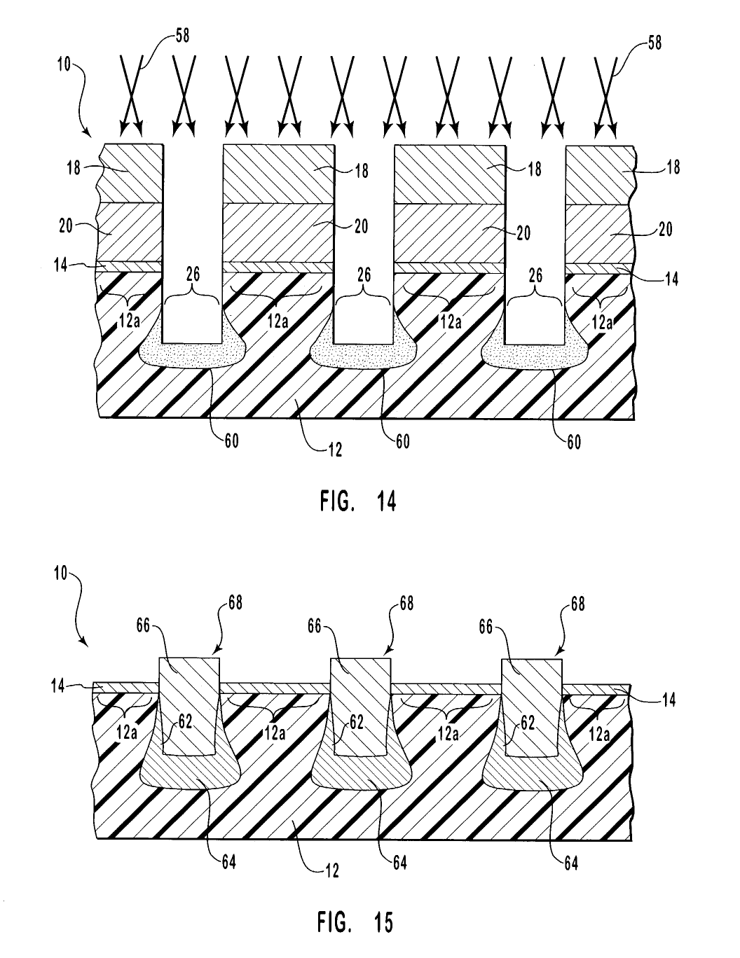

FIG. 13 illustrates a further step of the method of the present invention wherein an inner oxide layer 54 is deposited into isolation trenches 26. Silicon nitride hard mask 20 is subsequently removed in a conventional manner, such as CMP, using thin oxide layer 14 as a stopping point. A portion of inner oxide layer 54 is also etched away in so doing. The final result is the shallow trench isolation regions 56 shown in FIG. 13. As seen in FIG. 13, shallow trench isolation regions 56 extend into silicon substrate 12, and sidewall thermal oxide layer 50 together with bottom thermal oxide layer 52 form a lining layer that surrounds inner oxide layer 54. The bottom of the lining layer extends outward laterally to a substantially greater extent than the top of the lining layer in a manner that helps prevent cross-talk while consuming less of active regions 12a.

FIGS. 14 and 15 illustrate the above described method in an embodiment wherein the angle of ion implantation is greater than 0° from a direction orthogonal to the surface of semiconductor wafer 10 and less than 10° from the orthogonal direction. Shown in FIG. 14 is an angled ion implantation represented by arrows 58. The result of the angled ion implantation is the formation of implanted regions 60 at the bottom of isolation trenches 26 that are substantially larger and extend outward laterally more than implanted regions 48 of the non-angulated implant embodiment of FIGS. 11 through 13. An angle of implantation greater than about 10° from an orthogonal direction is undesirable in that it would cause a large amount of ions to be implanted into the sidewalls of isolation trenches 26, thereby causing a large portion of active regions 12a to be consumed when thermal oxidation is conducted.

Further steps of this embodiment are the same as in FIGS. 11 through 13. The resultant shallow trench isolation region 66 is shown in FIG. 15. Sidewall thermal oxidation layer 62 is slightly thicker than sidewall thermal oxide layer 50 of FIG. 13, and bottom thermal oxide layer 64 is substantially wider than bottom thermal oxide layer 52 of FIG. 13. This allows for even greater cross-talk prevention at the cost of very little of active region 12a.

The shallow trench isolation regions of FIGS. 13 and 15 can, as a result of the present invention, be formed thinner and can thus to be spaced closer together than prior art field regions formed by conventional LOCOS processes, while maintaining a high degree of protection against cross-talk. The closer spacing in turn allows for greater miniaturization of the integrated circuit being formed than can be accomplished with the use of conventional LOCOS processes.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method of forming a trench isolation region on a substrate assembly, the method comprising:
forming a trench in a volume of semiconductor material comprising a first material, the volume of semiconductor material being situated within a substrate assembly;
implanting ions of the first material into a surface of the trench;
oxidizing the surface of the trench by exposure to oxygen to form a thermal oxide layer comprising an oxide of the first material; and
filling the remainder of the trench with an insulating material.

2. The method of claim 1, wherein the ions of the first material comprise silicon ions.

3. The method of claim 2, wherein the first material comprises monocrystalline silicon.

4. The method of claim 1, wherein the substrate assembly is oriented within a major plane and implanting ions of the first material is conducted such that the direction that the ions are implanted into a selected region is within ten degrees from a direction that is orthogonal to the major plane of the substrate assembly.

5. The method of claim 1, wherein forming a trench in a volume of semiconductor material comprising a first material is conducted as a single etching process that etches adjacent and substantially contiguous nitride, oxide, and silicon layers.

6. The method of claim 1, wherein oxidizing the surface of the trench is conducted at a pressure in the range of about 5 to about 25 atmospheres.

7. The method of claim 1, wherein forming a trench in a volume of semiconductor material comprising a first material comprises:
forming a thin oxide layer on the volume of semiconductor material within the substrate assembly;
forming a layer of silicon nitride over the thin oxide layer;
forming a photoresist mask over the layer of silicon nitride; and
conducting a single etching process employing multiple etch recipes to etch the silicon nitride layer, the thin oxide layer, and the semiconductor material to form the trench.

8. A method of forming a shallow trench isolation region on a substrate assembly, the method comprising:
forming a trench in a volume of monocrystalline silicon within a substrate assembly;
implanting silicon ions into a surface of the trench;
oxidizing the surface of the trench by exposure of the trench to oxygen so as to form silicon dioxide on the surface of the trench; and
filling the trench with silicon dioxide.

9. The method of claim 8, wherein the substrate assembly is oriented within a major plane and the implanting of silicon ions is conducted such that the direction that the ions are implanted is within ten degrees from a direction that is orthogonal to the major plane of the substrate assembly.

10. The method of claim 8, wherein forming a trench in a volume of monocrystalline silicon is conducted as a single etching process that etches adjacent and substantially contiguous nitride, oxide, and silicon layers.

11. The method of claim 8, wherein oxidizing the surface of the trench is conducted at a pressure in the range of about 5 to about 25 atmospheres.

12. The method of claim 8, wherein forming a trench in a volume of monocrystalline silicon comprises:
forming a thin oxide layer on the volume of monocrystalline silicon within the substrate assembly;
forming a layer of silicon nitride over the thin oxide layer;
forming a photoresist mask over the layer of silicon nitride; and
conducting a single etching process employing multiple etch recipes to etch the silicon nitride layer, the thin oxide layer, and the monocrystalline silicon to form the trench.

13. A method of forming a shallow trench isolation region on a substrate assembly, the method comprising:
forming a thin oxide layer on a volume of silicon of a substrate assembly;
forming a layer of silicon nitride over the thin oxide layer;
forming a patterned photoresist mask over the layer of silicon nitride;
conducting an etching process that employs multiple etch recipes to etch the silicon nitride layer, the thin oxide layer, and the volume of silicon to form a trench in the volume of silicon;
implanting silicon ions into the trench, the silicon ions being implanted in a direction that is within ten degrees from a direction that is orthogonal to a plane of the substrate assembly;
oxidizing the surface of the trench by exposure to oxygen at a pressure in the range of about 5 to about 10 atmospheres so as to form a thermal oxide layer in the trench;
filling the remainder of the trench with silicon dioxide; and
removing the silicon nitride layer.
